(19) United States
(12) Patent Application Publication
(10) Pub. No.: US 2009/0243068 A1
(43) Pub. Date: Oct. 1, 2009

(54) INTEGRATED CIRCUIT PACKAGE SYSTEM WITH NON-SYMMETRICAL SUPPORT STRUCTURES

(76) Inventors: Heap Hoe Kuan, Singapore (SG); Seng Guan Chow, Singapore (SG); Lionel Chien Hui Tay, Singapore (SG)

Correspondence Address: LAW OFFICES OF MIKIO ISHIMARU, 333 W. EL CAMINO REAL, SUITE 330, SUNNYVALE, CA, 94087, US

(21) Appl. No.: 12/055,608

(22) Filed: Mar. 26, 2008

(51) Int. Cl. H01L 23/12; H01L 21/58

(52) U.S. Cl. 257/686; 438/108; 438/127; 438/109; 257/E21.502; 257/E21.499; 257/E23.003

(57) ABSTRACT

An integrated circuit package system including: providing a substrate with a wire-bonded die mounted thereover; mounting a first support structure and a second support structure of different size above the substrate; mounting a structure above the first support structure and the second support structure; and encapsulating the wire-bonded die, the first support structure and the second support structure with an encapsulation.

### CROSS-REFERENCE TO RELATED APPLICATION

The present application contains subject matter related to a concurrently filed U.S. patent application by WonJun Ko, BoHan Yoon, and JoungUn Park entitled “INTEGRATED CIRCUIT PACKAGE SYSTEM WITH SUPPORT STRUCTURE UNDER WIRE-IN-FILM ADHESIVE”. The related application is assigned to STATS ChipPAC Ltd. and is identified by docket number 27-504.

### TECHNICAL FIELD

The present invention relates generally to integrated circuits, and more particularly to a system for non-symmetrical support structures in an integrated circuit package system.

### BACKGROUND ART

The rapidly growing portable electronics market, e.g. cellular phones, laptop computers, and PDAs, are an integral facet of modern life. The multitude of portable devices represents one of the largest potential market opportunities for next generation packaging. These devices have unique attributes which have significant impacts on manufacturing integration, in that they must be generally small, light weight, and rich in functionality and they must be produced in high volumes at relatively low cost.

As an extension of the semiconductor industry, the electronics packaging industry has witnessed ever-increasing commercial competitive pressures, along with growing consumer expectations and the diminishing opportunities for meaningful product differentiation in the marketplace.

Packaging and materials engineering and development are at the very core of these next generation electronics insertion strategies outlined in road maps for development of next generation products. Future electronic systems may be more intelligent, have higher density, use less power, operate at higher speed, and may include mixed technology devices and assembly structures at lower cost than today.

Current packaging suppliers are struggling to accommodate the high speed computer devices which are projected to exceed one TeraHertz (THz) in the near future. The current technologies, materials, equipment, and structures offer challenges to the basic assembly of these new devices while still not adequately addressing cooling and reliability concerns.

The envelope of technical capability of next level interconnect assemblies are not yet known, and no clear cost effective technology has yet been identified. Beyond the performance requirements of next generation devices, the industry now demands that cost be a primary product differentiator in an attempt to meet profit goals.

As a result, the road maps are driving electronics packaging to precision, ultra miniature form factors which require automation in order to achieve acceptable yield. These challenges demand not only automation of manufacturing, but also the automation of data flow and information to the production manager and customer.

There have been many approaches to addressing the advanced packaging requirements of microprocessors and portable electronics with successive generations of semiconductors. Many industry road maps have identified significant gaps between the current semiconductor capability and the available supporting electronic packaging technologies. The limitations and issues with current technologies include increasing clock rates, EMI radiation, thermal loads, second level assembly reliability stresses and cost.

As these package systems evolve to incorporate more components with varied environmental needs, the pressure to push the technological envelope becomes increasingly challenging. More significantly, with the ever-increasing complexity, the potential risk of error increases greatly during manufacture.

In view of the ever-increasing commercial competitive pressures, along with growing consumer expectations and the diminishing opportunities for meaningful product differentiation in the marketplace, it is critical that answers be found for these problems. Additionally, the need to reduce costs, reduce production time, improve efficiencies and performance, and meet competitive pressures, adds an even greater urgency to the critical necessity for finding answers to these problems.

Thus a need still remains for smaller footprints and more robust packages and methods for manufacture. Solutions to these problems have been long sought but prior developments have not taught or suggested any solutions and, thus, solutions to these problems have long eluded those skilled in the art.

### DISCLOSURE OF THE INVENTION

The present invention provides an integrated circuit package system including: providing a substrate with a wire-bonded die mounted thereover; mounting a first support structure and a second support structure of different size above the substrate; mounting a structure above the first support structure and the second support structure; and encapsulating the wire-bonded die, the first support structure and the second support structure with an encapsulation.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 a top view of an integrated circuit package system, in a first embodiment of the present invention;

FIG. 2 is a cross sectional view of the integrated circuit package system along the line 2-2 of FIG. 1;

FIG. 3 is a cross sectional view of an integrated circuit package system in a second embodiment of the present invention;

FIG. 4 is a cross sectional view of an integrated circuit package system in a third embodiment of the present invention;

FIG. 5 is a cross sectional view of an integrated circuit package system in a fourth embodiment of the present invention;

FIG. 6 is a cross sectional view of an integrated circuit package system in a fifth embodiment of the present invention;

FIG. 7 is a cross sectional view of an integrated circuit package system in a sixth embodiment of the present invention;

FIG. 8 is a cross sectional view of an integrated circuit package system in a seventh embodiment of the present invention;

FIG. 9 is a cross sectional view of an integrated circuit package system in an eighth embodiment of the present invention;

FIG. 10 is a cross sectional view of an integrated circuit package system in a ninth embodiment of the present invention;

FIG. 11 is a cross sectional view of an integrated circuit package system in a tenth embodiment of the present invention;

FIG. 12 is a cross sectional view of an integrated circuit package system in an eleventh embodiment of the present invention;

FIG. 13 is a cross sectional view of an integrated circuit package system in a twelfth embodiment of the present invention;

FIG. 14 is a cross sectional view of an integrated circuit package system in a thirteenth embodiment of the present invention;

FIG. 15 is a cross sectional view of an integrated circuit package system in a fourteenth embodiment of the present invention;

FIG. 16 is a cross sectional view of an integrated circuit package system in a fifteenth embodiment of the present invention;

FIG. 17 is a cross sectional view of an integrated circuit package system in a sixteenth embodiment of the present invention;

FIG. 18 is a cross sectional view of an integrated circuit package system in a seventeenth embodiment of the present invention; and

FIG. 19 is a flow chart of an integrated circuit package system for manufacture of an integrated circuit package system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the system are semi-diagrammatic and not to scale and, particularly, some of the dimensions are for the clarity of presentation and are shown greatly exaggerated in the drawing FIGs. The same numbers are used in all the drawing FIGs. to relate to the same elements.

For expository purposes, the term “horizontal” as used herein is defined as a plane parallel to the plane or surface of the substrate, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means that there is direct contact among elements.

The term “processing” as used herein includes deposition of material or photoresist, patterning, exposure, development, etching, cleaning, and/or removal of the material or photoresist as required in forming a described structure.

The term “system” as used herein refers to and is defined as the method and as the apparatus of the present invention in accordance with the context in which the term is used. The embodiments have been numbered first embodiment, second embodiment, etc. as a matter of descriptive convenience and are not intended to have any other significance or provide limitations for the present invention.

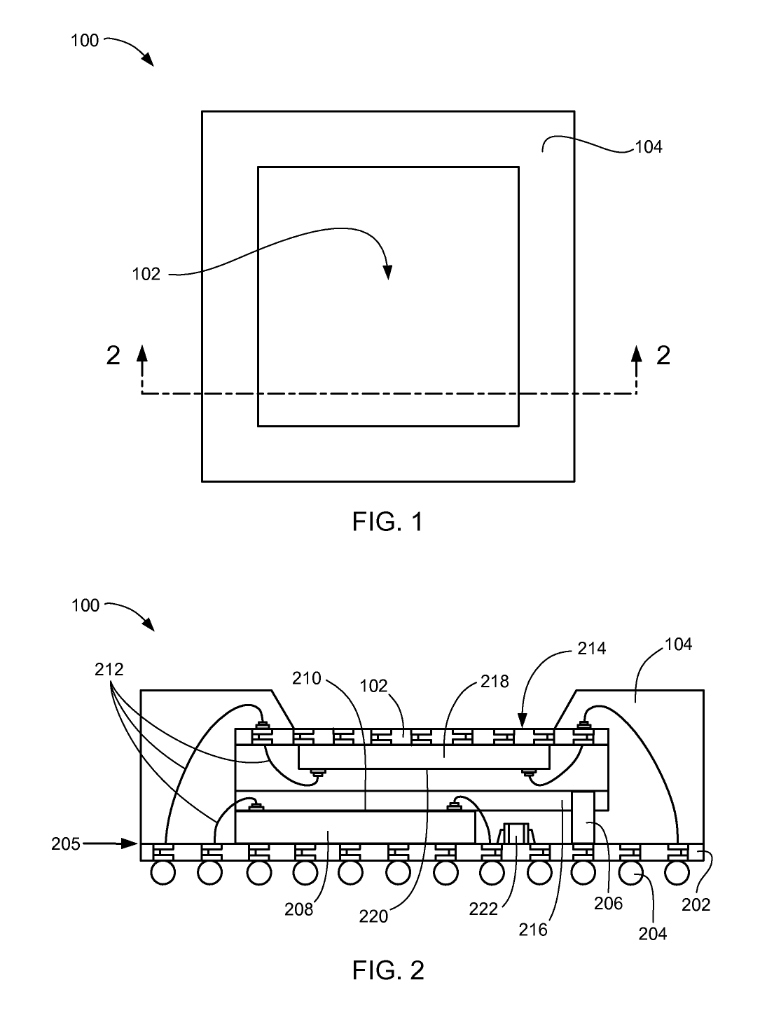

Referring now to FIG. 1, therein is shown a top view of an integrated circuit package system 100, in a first embodiment of the present invention. The integrated circuit package system 100 is shown having an inner stacking module (ISM) substrate 102 such as a laminated plastic or ceramic substrate. The ISM substrate 102 is encapsulated by an encapsulation 104 such as an epoxy mold compound (EMC).

Referring now to FIG. 2, therein is shown a cross sectional view of the integrated circuit package system 100 along the line 2-2 of FIG. 1. The integrated circuit package system 100 is shown having a substrate 202 such as a laminated plastic or ceramic substrate. Below the substrate, external interconnects such as solder balls 204 are connected.

The substrate 202 creates a reference plane 205, above which, a first support structure such as a first pillar 206 is mounted. The first pillar 206 may be an organic or conductive metal pillar. Also mounted above the substrate 202 is a second support structure such as a wire-bonded die 208 with an active side 210.

The active side 210 of the wire-bonded die 208 is connected to the substrate 202 by bond wires 212. Above the wire-bonded die 208 and the first pillar 206 is a structure such as an ISM 214. Another structure may be mounted above the ISM 214 to further increase density. Between the ISM 214 and the wire-bonded die 208, is a wire-in-film adhesive 216.

The wire-in-film adhesive 216 has a low viscosity and, as temperature increases, the viscosity gets lower. Therefore, the wire-in-film adhesive 216 can be easily pressed over the bond wires 212 and above and around the wire-bonded die 208 and then cured to harden the wire-in-film adhesive 216.

It has been discovered that the wire-in-film adhesive 216 should be a thermally conductive dielectric material. The wire-in-film adhesive 216 can be made of a B-stage material that can be hardened after curing and can maintain a predetermined thickness.

The first pillar 206 penetrates the wire-in-film adhesive 216 and contacts the ISM 214 making the first pillar 206 a different size than the wire-bonded die 208. Together the wire-bonded die 208 and the first pillar 206 support the ISM 214 over the substrate 202.

The ISM 214 is shown connected from above to the substrate 202 with the bond wires 212. The ISM 214 is shown having the ISM substrate 102 with an ISM wire-bonded die 218 mounted below and having an active side 220.

The active side 220 of the ISM wire-bonded die 218 is connected to the ISM substrate 102 with the bond wires 212. Further, above the substrate 202 passive components 222 such as capacitors, resistors or the like may be mounted. The encapsulation 104 encapsulates the wire-bonded die 208, the first pillar 206 and the bond wires 212 protecting sensitive components from moisture, dust and other contamination.

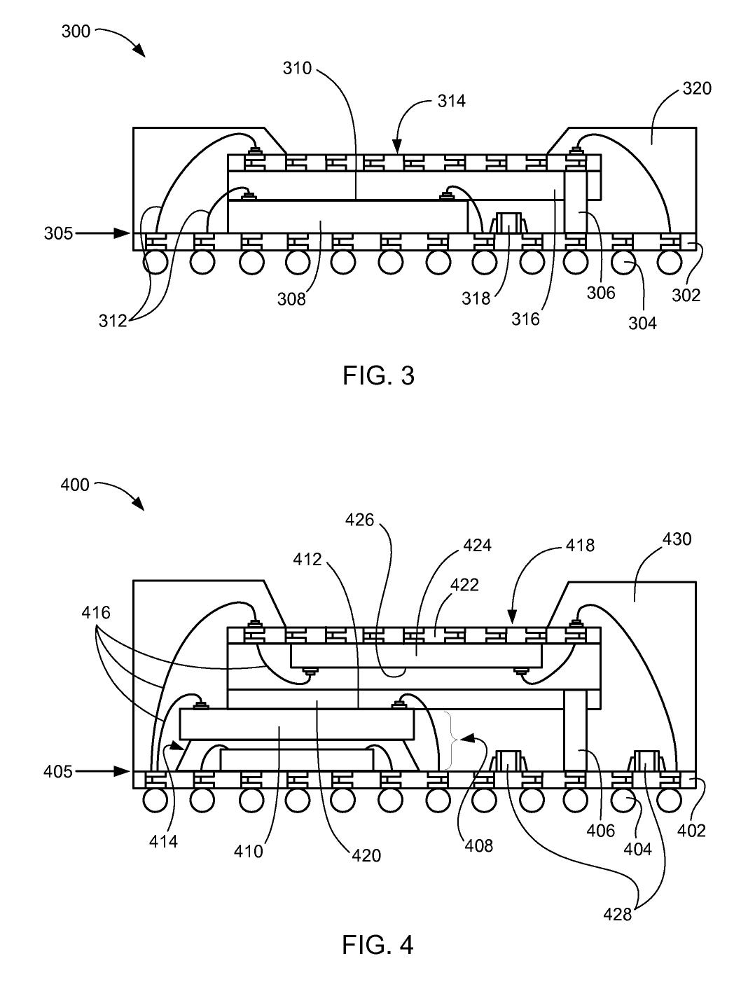

Referring now to FIG. 3, therein is shown a cross sectional view of an integrated circuit package system 300 in a second embodiment of the present invention. The integrated circuit package system 300 is shown having a substrate 302 such as a laminated plastic or ceramic substrate.

Below the substrate, external interconnects such as solder balls 304 are connected. The substrate 302 creates a reference plane 305, above which, a first support structure such as a first pillar 306 is mounted. The first pillar 306 may be an organic or conductive metal pillar. Also mounted above the substrate 302 is a second support structure such as a wire-bonded die 308 with an active side 310.

The active side 310 of the wire-bonded die 308 is connected to the substrate 302 by bond wires 312. Above the wire-bonded die 308 and the first pillar 306 is a structure such as an interposer 314. Another structure may be mounted above the interposer 314 to further increase density. Between the interposer 314 and the wire-bonded die 308, is a wire-in-film adhesive 316.

The wire-in-film adhesive 316 has a low viscosity and, as temperature increases, the viscosity gets lower. Therefore, the wire-in-film adhesive 316 can be easily pressed over the bond wires 312 and above and around the wire-bonded die 308 and then cured to harden the wire-in-film adhesive 316.

It has been discovered that the wire-in-film adhesive 316 should be a thermally conductive dielectric material. The wire-in-film adhesive 316 can be made of a B-stage material that can be hardened after curing and can maintain a predetermined thickness.

The first pillar 306 penetrates the wire-in-film adhesive 316 and contacts the interposer 314 making the first pillar 306 a different size than the wire-bonded die 308. Together the wire-bonded die 308 and the first pillar 306 support the interposer 314 over the substrate 302.

The interposer 314 is shown connected from above to the substrate 302 with the bond wires 312. Further, above the substrate 302 passive components 318 such as capacitors, resistors or the like may be mounted. An encapsulation 320 encapsulates the wire-bonded die 308, the first pillar 306 and the bond wires 312 protecting sensitive components from moisture, dust and other contamination.

Referring now to FIG. 4, therein is shown a cross sectional view of an integrated circuit package system 400 in a third embodiment of the present invention. The integrated circuit package system 400 is shown having a substrate 402 such as a laminated plastic or ceramic substrate.

Below the substrate, external interconnects such as solder balls 404 are connected. The substrate 402 creates a reference plane 405, above which, a first support structure such as a first pillar 406 is mounted. The first pillar 406 may be an organic or conductive metal pillar. Also mounted above the substrate 402 is a second support structure 408 consisting of a wire-bonded die 410 with an active side 412 above a pre-mold package 414.

The pre-mold package 414 is between the wire-bonded die 410 and the substrate 402. The active side 412 of the wire-bonded die 410 is connected to the substrate 402 by bond wires 416. Above the wire-bonded die 410 and the first pillar 406 is a structure such as an ISM 418. Another structure may be mounted above the ISM 418 to further increase density. Between the ISM 418 and the wire-bonded die 410, is a wire-in-film adhesive 420.

The wire-in-film adhesive 420 has a low viscosity and, as temperature increases, the viscosity gets lower. Therefore, the wire-in-film adhesive 420 can be easily pressed over the bond wires 416 and above and around the wire-bonded die 410 and then cured to harden the wire-in-film adhesive 420.

It has been discovered that the wire-in-film adhesive 420 should be a thermally conductive dielectric material. The wire-in-film adhesive 420 can be made of a B-stage material that can be hardened after curing and can maintain a predetermined thickness.

The first pillar 406 penetrates the wire-in-film adhesive 420 and contacts the ISM 418 making the first pillar 406 a different size than the second support structure 408. Together the wire-bonded die 410, the pre-mold package 414, and the first pillar 406 support the ISM 418 over the substrate 402.

The ISM 418 is shown connected from above to the substrate 402 with the bond wires 416. The ISM 418 is shown having an ISM substrate 422 with an ISM wire-bonded die 424 mounted below and having an active side 426.

The active side 426 of the ISM wire-bonded die 424 is connected to the ISM substrate 422 with the bond wires 416. Further, above the substrate 402 passive components 428 such as capacitors, resistors or the like may be mounted. An encapsulation 430 encapsulates the wire-bonded die 410, the first pillar 406 and the bond wires 416 protecting sensitive components from moisture, dust and other contamination.

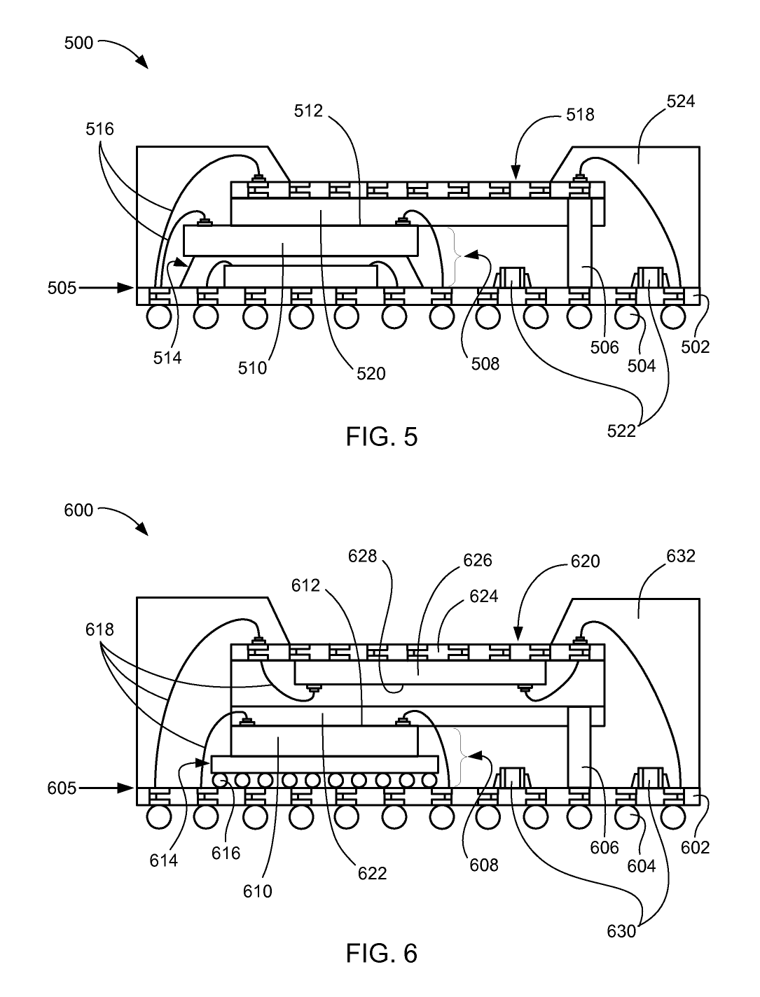

Referring now to FIG. 5, therein is shown a cross sectional view of an integrated circuit package system 500 in a fourth embodiment of the present invention. The integrated circuit package system 500 is shown having a substrate 502 such as a laminated plastic or ceramic substrate.

Below the substrate, external interconnects such as solder balls 504 are connected. The substrate 502 creates a reference plane 505, above which, a first support structure such as a first pillar 506 is mounted.

The first pillar 506 may be an organic or conductive metal pillar. Also mounted above the substrate 502 is a second support structure 508 consisting of a wire-bonded die 510 with an active side 512 above a pre-mold package 514.

The pre-mold package 514 is between the wire-bonded die 510 and the substrate 502. The active side 512 of the wire-bonded die 510 is connected to the substrate 502 by bond wires 516. Above the wire-bonded die 510 and the first pillar 506 is a structure such as an interposer 518. Another structure may be mounted above the interposer 518 to further increase density.

Between the interposer 518 and the wire-bonded die 510, is a wire-in-film adhesive 520. The wire-in-film adhesive 520 has a low viscosity and, as temperature increases, the viscosity gets lower.

Therefore, the wire-in-film adhesive 520 can be easily pressed over the bond wires 516 and above and around the wire-bonded die 510 and then cured to harden the wire-in-film adhesive 520.

It has been discovered that the wire-in-film adhesive 520 should be a thermally conductive dielectric material. The wire-in-film adhesive 520 can be made of a B-stage material that can be hardened after curing and can maintain a predetermined thickness.

The first pillar 506 penetrates the wire-in-film adhesive 520 and contacts the interposer 518 making the first pillar 506 a different size than the second support structure 508. Together the wire-bonded die 510, the pre-mold package 514, and the first pillar 506 support the interposer 518 over the substrate 502.

The interposer 518 is shown connected from above to the substrate 502 with the bond wires 516. Further, above the substrate 502 passive components 522 such as capacitors, resistors or the like may be mounted. An encapsulation 524 encapsulates the wire-bonded die 510, the first pillar 506 and the bond wires 516 protecting sensitive components from moisture, dust and other contamination.

Referring now to FIG. 6, therein is shown a cross sectional view of an integrated circuit package system 600 in a fifth embodiment of the present invention. The integrated circuit package system 600 is shown having a substrate 602 such as a laminated plastic or ceramic substrate.

Below the substrate, external interconnects such as solder balls 604 are connected. The substrate 602 creates a reference plane 605, above which, a first support structure such as a first pillar 606 is mounted.

The first pillar 606 may be an organic or conductive metal pillar. Also mounted above the substrate 602 is a second support structure 608 consisting of a wire-bonded die 610 with an active side 612 above a flip chip (FC) 614. The FC 614 is between the wire-bonded die 610 and the substrate 602 and connected to the substrate with FC solder balls 616.

The active side 612 of the wire-bonded die 610 is connected to the substrate 602 by bond wires 618. Above the wire-bonded die 610 and the first pillar 606 is a structure such as an ISM 620. Another structure may be mounted above the ISM 620 to further increase density. Between the ISM 620 and the wire-bonded die 610, is a wire-in-film adhesive 622.

The wire-in-film adhesive 622 has a low viscosity and, as temperature increases, the viscosity gets lower. Therefore, the wire-in-film adhesive 622 can be easily pressed over the bond wires 618 and above and around the wire-bonded die 610 and then cured to harden the wire-in-film adhesive 622.

It has been discovered that the wire-in-film adhesive 622 should be a thermally conductive dielectric material. The wire-in-film adhesive 622 can be made of a B-stage material that can be hardened after curing and can maintain a predetermined thickness.

The first pillar 606 penetrates the wire-in-film adhesive 622 and contacts the ISM 620 making the first pillar 606 a different size than the second support structure 608. Together the wire-bonded die 610, the FC 614, and the first pillar 606 support the ISM 620 over the substrate 602. The ISM 620 is shown connected from above to the substrate 602 with the bond wires 618.

The ISM 620 is shown having an ISM substrate 624 with an ISM wire-bonded die 626 mounted below and having an active side 628. The active side 628 of the ISM wire-bonded die 626 is connected to the ISM substrate 624 with the bond wires 618.

Further, above the substrate 602 passive components 630 such as capacitors, resistors or the like may be mounted. An encapsulation 632 encapsulates the wire-bonded die 610, the first pillar 606 and the bond wires 618 protecting sensitive components from moisture, dust and other contamination.

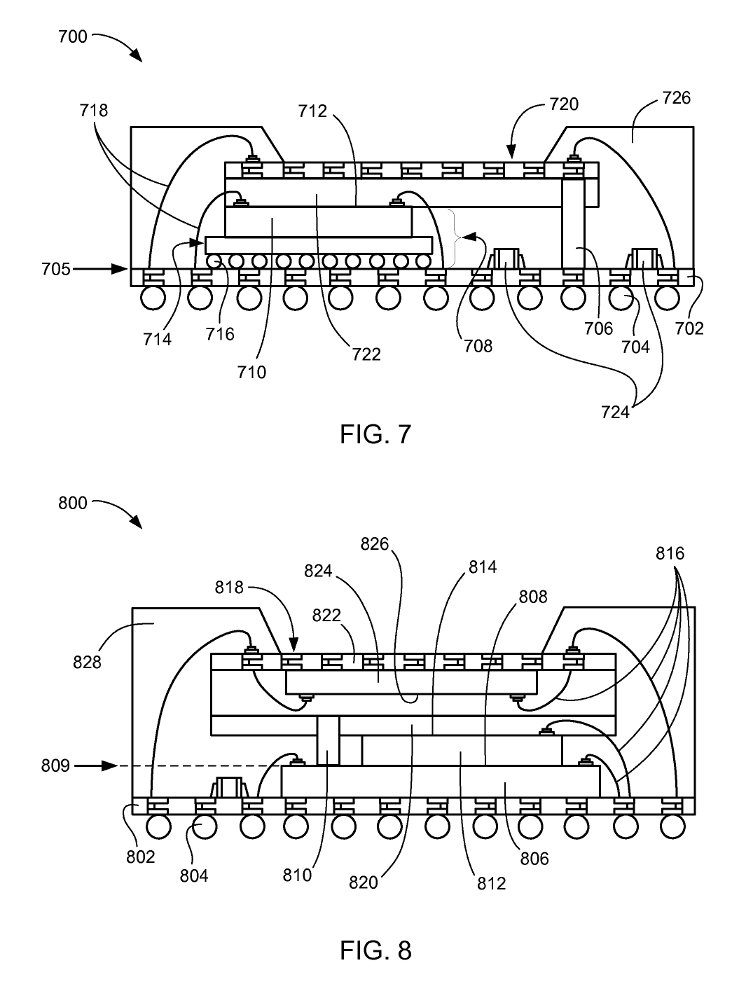

Referring now to FIG. 7, therein is shown a cross sectional view of an integrated circuit package system 700 in a sixth embodiment of the present invention. The integrated circuit package system 700 is shown having a substrate 702 such as a laminated plastic or ceramic substrate.

Below the substrate, external interconnects such as solder balls 704 are connected. The substrate 702 creates a reference plane 705, above which, a first support structure such as a first pillar 706 is mounted. The first pillar 706 may be an organic or conductive metal pillar.

Also mounted above the substrate 702 is a second support structure 708 consisting of a wire-bonded die 710 with an active side 712 above a FC 714. The FC 714 is between the wire-bonded die 710 and the substrate 702 and connected to the substrate with FC solder balls 716. The active side 712 of the wire-bonded die 710 is connected to the substrate 702 by bond wires 718.

Above the wire-bonded die 710 and the first pillar 706 is a structure such as an interposer 720. Another structure may be mounted above the interposer 720 to further increase density. Between the interposer 720 and the wire-bonded die 710, is a wire-in-film adhesive 722. The wire-in-film adhesive 722 has a low viscosity and, as temperature increases, the viscosity gets lower.

Therefore, the wire-in-film adhesive 722 can be easily pressed over the bond wires 718 and above and around the wire-bonded die 710 and then cured to harden the wire-in-film adhesive 722.

It has been discovered that the wire-in-film adhesive 722 should be a thermally conductive dielectric material. The wire-in-film adhesive 722 can be made of a B-stage material that can be hardened after curing and can maintain a predetermined thickness.

The first pillar 706 penetrates the wire-in-film adhesive 722 and contacts the interposer 720 making the first pillar 706 a different size than the second support structure 708. Together the wire-bonded die 710, the FC 714, and the first pillar 706 support the interposer 720 over the substrate 702.

The interposer 720 is shown connected from above to the substrate 702 with the bond wires 718. Further, above the substrate 702 passive components 724 such as capacitors, resistors or the like may be mounted. An encapsulation 726 encapsulates the wire-bonded die 710, the first pillar 706 and the bond wires 718 protecting sensitive components from moisture, dust and other contamination.

Referring now to FIG. 8, therein is shown a cross sectional view of an integrated circuit package system 800 in a seventh embodiment of the present invention. The integrated circuit package system 800 is shown having a substrate 802 such as a laminated plastic or ceramic substrate.

Below the substrate, external interconnects such as solder balls 804 are connected. Mounted above the substrate 802 is a first wire-bonded die 806 with an active side 808. The active side 808 creates a reference plane 809, above which, a first support structure such as a first pillar 810 is mounted.

The first pillar 810 may be an organic or conductive metal pillar. Also mounted above the first wire-bonded die 806 is a second support structure such as a wire-bonded die 812 with an active side 814.

The active side 814 of the wire-bonded die 812, and the active side 808 of the first wire-bonded die 806 are connected to the substrate 802 by bond wires 816. Above the wire-bonded die 812 and the first pillar 810 is a structure such as an ISM 818. Another structure may be mounted above the ISM 818 to further increase density. Between the ISM 818 and the wire-bonded die 812, is a wire-in-film adhesive 820.

The wire-in-film adhesive 820 has a low viscosity and, as temperature increases, the viscosity gets lower. Therefore, the wire-in-film adhesive 820 can be easily pressed over the bond wires 816 and above and around the wire-bonded die 812 and then cured to harden the wire-in-film adhesive 820.

It has been discovered that the wire-in-film adhesive 820 should be a thermally conductive dielectric material. The wire-in-film adhesive 820 can be made of a B-stage material that can be hardened after curing and can maintain a predetermined thickness.

The first pillar 810 penetrates the wire-in-film adhesive 820 and contacts the ISM 818 making the first pillar 810 a different size than the wire-bonded die 812. Together the wire-bonded die 812 and the first pillar 810 support the ISM 818 over the substrate 802.

The ISM 818 is shown connected from above to the substrate 802 with the bond wires 816. The ISM 818 is shown having an ISM substrate 822 with an ISM wire-bonded die 824 mounted below and having an active side 826.

The active side 826 of the ISM wire-bonded die 824 is connected to the ISM substrate 822 with the bond wires 816. An encapsulation 828 encapsulates the wire-bonded die 812, the first pillar 810 and the bond wires 816 protecting sensitive components from moisture, dust and other contamination.

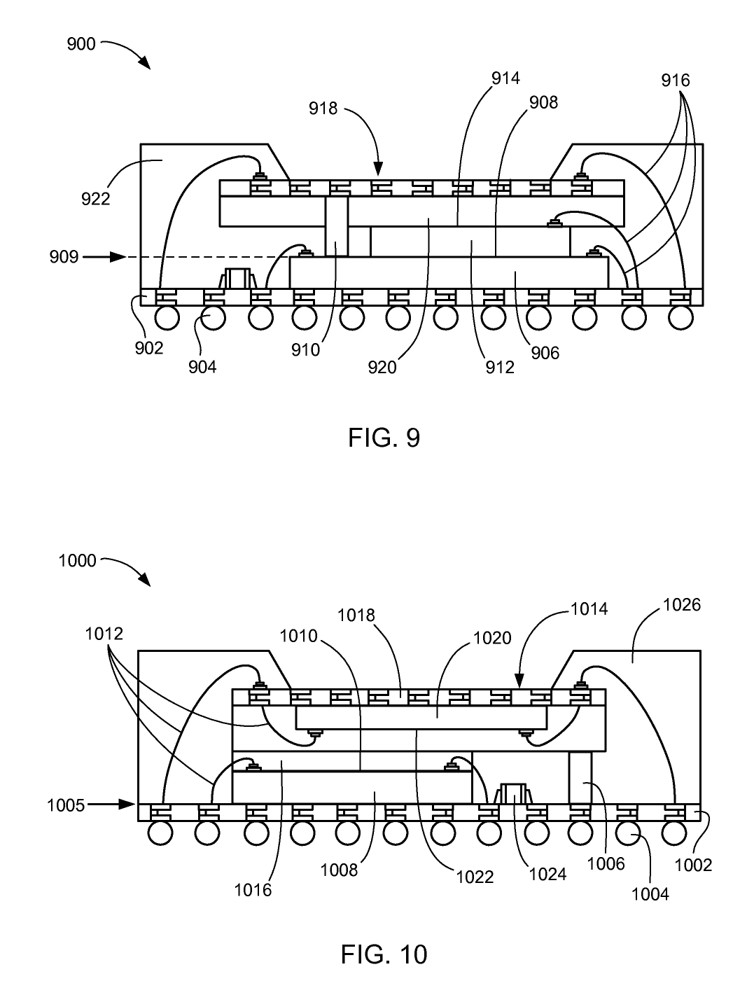

Referring now to FIG. 9, therein is shown a cross sectional view of an integrated circuit package system 900 in an eighth embodiment of the present invention. The integrated circuit package system 900 is shown having a substrate 902 such as a laminated plastic or ceramic substrate.

Below the substrate, external interconnects such as solder balls 904 are connected. Mounted above the substrate 902 is a first wire-bonded die 906 with an active side 908. The active side 908 creates a reference plane 909, above which, a first support structure such as a first pillar 910 is mounted.

The first pillar 910 may be an organic or conductive metal pillar. Also mounted above the first wire-bonded die 906 is a second support structure such as a wire-bonded die 912 with an active side 914.

The active side 914 of the wire-bonded die 912, and the active side 908 of the first wire-bonded die 906 are connected to the substrate 902 by bond wires 916. Above the wire-bonded die 912 and the first pillar 910 is a structure such as an interposer 918. Another structure may be mounted above the interposer 918 to further increase density.

Between the interposer 918 and the wire-bonded die 912, is a wire-in-film adhesive 920. The wire-in-film adhesive 920 has a low viscosity and, as temperature increases, the viscosity gets lower.

Therefore, the wire-in-film adhesive 920 can be easily pressed over the bond wires 916 and above and around the wire-bonded die 912 and then cured to harden the wire-in-film adhesive 920.

It has been discovered that the wire-in-film adhesive 920 should be a thermally conductive dielectric material. The wire-in-film adhesive 920 can be made of a B-stage material that can be hardened after curing and can maintain a predetermined thickness.

The first pillar 910 penetrates the wire-in-film adhesive 920 and contacts the interposer 918 making the first pillar 910 a different size than the wire-bonded die 912. Together the wire-bonded die 912 and the first pillar 910 support the interposer 918 over the substrate 902.

The interposer 918 is shown connected from above to the substrate 902 with the bond wires 916. An encapsulation 922 encapsulates the wire-bonded die 912, the first pillar 910 and the bond wires 916 protecting sensitive components from moisture, dust and other contamination.

Referring now to FIG. 10, therein is shown a cross sectional view of an integrated circuit package system 1000 in a ninth embodiment of the present invention. The integrated circuit package system 1000 is shown having a substrate 1002 such as a laminated plastic or ceramic substrate.

Below the substrate, external interconnects such as solder balls 1004 are connected. The substrate 1002 creates a reference plane 1005, above which, a first support structure such as a first pillar 1006 is mounted. The first pillar 1006 may be an organic or conductive metal pillar.

Also mounted above the substrate 1002 is a second support structure such as a wire-bonded die 1008 with an active side 1010. The active side 1010 of the wire-bonded die 1008 is connected to the substrate 1002 by bond wires 1012.

Above the wire-bonded die 1008 and the first pillar 1006 is a structure such as an ISM 1014. Another structure may be mounted above the ISM 1014 to further increase density. Between the ISM 1014 and the wire-bonded die 1008, is a wire-in-film adhesive 1016. The wire-in-film adhesive 1016 has a low viscosity and, as temperature increases, the viscosity gets lower.

Therefore, the wire-in-film adhesive 1016 can be easily pressed over the bond wires 1012 and above and around the wire-bonded die 1008 and then cured to harden the wire-in-film adhesive 1016.

It has been discovered that the wire-in-film adhesive 1016 should be a thermally conductive dielectric material. The wire-in-film adhesive 1016 can be made of a B-stage material that can be hardened after curing and can maintain a predetermined thickness.

The first pillar 1006 extends from the substrate 1002 to the ISM 1014 making the first pillar 1006 a different size than the wire-bonded die 1008. The first pillar 1006 does not penetrate the wire-in-film adhesive 1016.

Together the wire-bonded die 1008 and the first pillar 1006 support the ISM 1014 over the substrate 1002. The ISM 1014 is shown connected from above to the substrate 1002 with the bond wires 1012. The ISM 1014 is shown having an ISM substrate 1018 with an ISM wire-bonded die 1020 mounted below and having an active side 1022.

The active side 1022 of the ISM wire-bonded die 1020 is connected to the ISM substrate 1018 with the bond wires 1012. Further, above the substrate 1002 passive components 1024 such as capacitors, resistors or the like may be mounted.

An encapsulation 1026 encapsulates the wire-bonded die 1008, the first pillar 1006 and the bond wires 1012 protecting sensitive components from moisture, dust and other contamination.

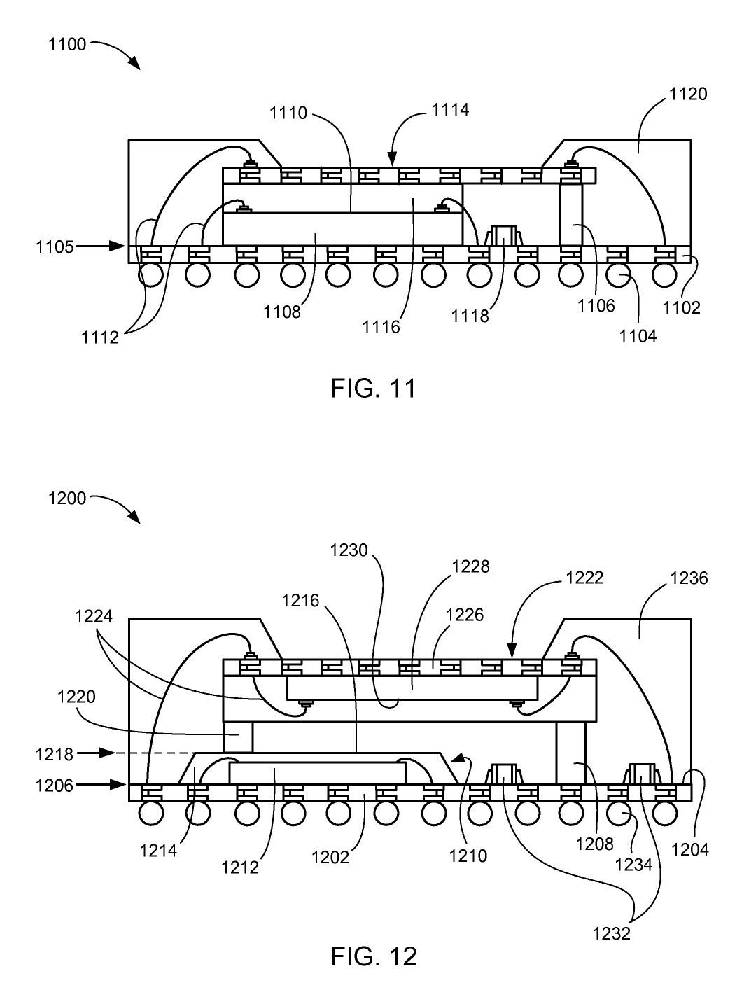

Referring now to FIG. 11, therein is shown a cross sectional view of an integrated circuit package system 1100 in a tenth embodiment of the present invention. The integrated circuit package system 1100 is shown having a substrate 1102 such as a laminated plastic or ceramic substrate.

Below the substrate, external interconnects such as solder balls 1104 are connected. The substrate 1102 creates a reference plane 1105, above which, a first support structure such as a first pillar 1106 is mounted.

The first pillar 1106 may be an organic or conductive metal pillar. Also mounted above the substrate 1102 is a second support structure such as a wire-bonded die 1108 with an active side 1110.

The active side 1110 of the wire-bonded die 1108 is connected to the substrate 1102 by bond wires 1112. Above the wire-bonded die 1108 and the first pillar 1106 is a structure such as an interposer 1114. Another structure may be mounted above the interposer 1114 to further increase density. Between the interposer 1114 and the wire-bonded die 1108, is a wire-in-film adhesive 1116.

The wire-in-film adhesive 1116 has a low viscosity and, as temperature increases, the viscosity gets lower. Therefore, the wire-in-film adhesive 1116 can be easily pressed over the bond wires 1112 and above and around the wire-bonded die 1108 and then cured to harden the wire-in-film adhesive 1116.

It has been discovered that the wire-in-film adhesive 1116 should be a thermally conductive dielectric material. The wire-in-film adhesive 1116 can be made of a B-stage material that can be hardened after curing and can maintain a predetermined thickness.

The first pillar 1106 extends from the substrate 1102 to the interposer 1114 making the first pillar 1106 a different size than the wire-bonded die 1108. The first pillar 1106 does not penetrate the wire-in-film adhesive 1116.

Together the wire-bonded die 1108 and the first pillar 1106 support the interposer 1114 over the substrate 1102. The interposer 1114 is shown connected from above to the substrate 1102 with the bond wires 1112.

Further, above the substrate 1102 passive components 1118 such as capacitors, resistors or the like may be mounted. An encapsulation 1120 encapsulates the wire-bonded die 1108, the first pillar 1106 and the bond wires 1112 protecting sensitive components from moisture, dust and other contamination.

Referring now to FIG. 12, therein is shown a cross sectional view of an integrated circuit package system 1200 in an eleventh embodiment of the present invention. The integrated circuit package system 1200 is shown having a substrate 1202 such as a laminated plastic or ceramic substrate with a top surface 1204.

The top surface 1204 of the substrate 1202 creates a reference plane 1206 on which a first support structure such as a first pillar 1208 is mounted. The first pillar 1208 may be an organic or conductive metal pillar.

Also mounted above the substrate 1202 is a pre-mold package 1210. The pre-mold package 1210 consists of a pre-mold wire-bonded die 1212 and a pre-mold encapsulation 1214 encapsulating the pre-mold wire-bonded die 1212.

The pre-mold encapsulation 1214 has a top surface 1216. The top surface 1216 of the pre-mold encapsulation 1214 creates a reference plane 1218 on which a second support structure such as a second pillar 1220 is mounted. Above the first pillar 1208 and the second pillar 1220 is a structure such as an ISM 1222.

The first pillar 1208 extends from the reference plane 1206 and contacts the ISM 1222 making the first pillar 1208 a different size than the second pillar 1220 which extends from the reference plane 1218 and contacts the ISM 1222.

The ISM 1222 is shown connected from above to the substrate 1202 with bond wires 1224. The ISM 1222 is shown having an ISM substrate 1226 with an ISM wire-bonded die 1228 mounted below and having an active side 1230.

The active side 1230 of the ISM wire-bonded die 1228 is connected to the ISM substrate 1226 with the bond wires 1224. Further, above the substrate 1202 passive components 1232 such as capacitors, resistors or the like may be mounted.

Below the substrate 1202 are mounted external interconnects such as solder balls 1234. An encapsulation 1236 encapsulates the first pillar 1208, the second pillar 1220, and the pre-mold package 1210 protecting sensitive components from moisture, dust and other contamination.

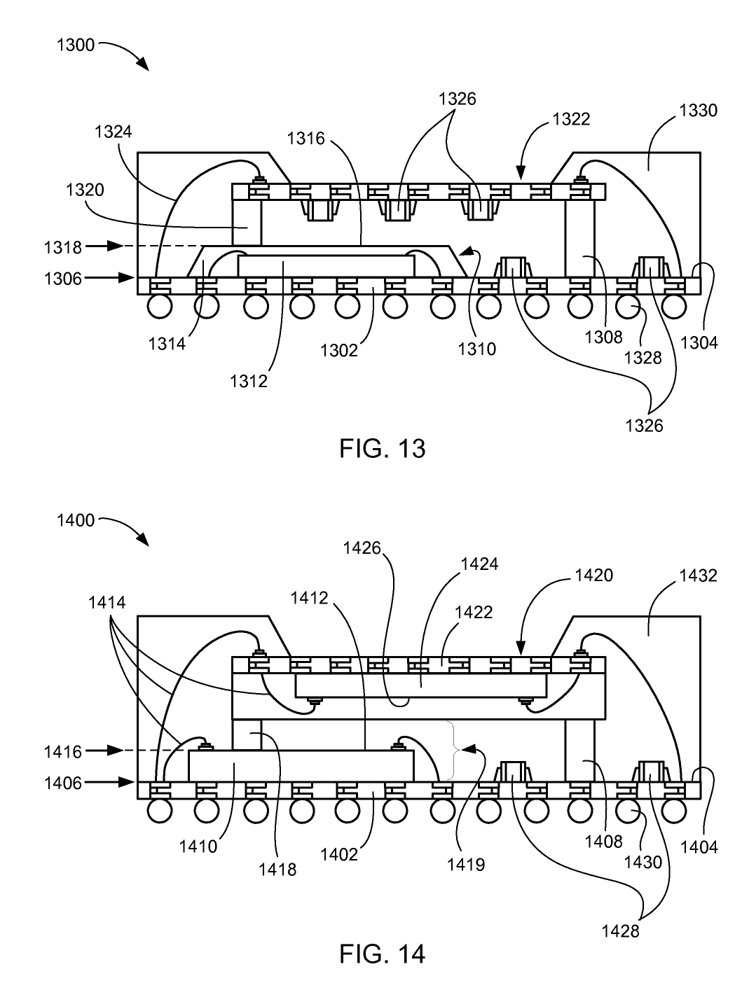

Referring now to FIG. 13, therein is shown a cross sectional view of an integrated circuit package system 1300 in a twelfth embodiment of the present invention. The integrated circuit package system 1300 is shown having a substrate 1302 such as a laminated plastic or ceramic substrate with a top surface 1304.

The top surface 1304 of the substrate 1302 creates a reference plane 1306 on which a first support structure such as a first pillar 1308 is mounted. The first pillar 1308 may be an organic or conductive metal pillar.

Also mounted above the substrate 1302 is a pre-mold package 1310. The pre-mold package consists of a pre-mold wire-bonded die 1312 and a pre-mold encapsulation 1314 encapsulating the pre-mold wire-bonded die 1312. The pre-mold encapsulation 1314 has a top surface 1316.

The top surface 1316 of the pre-mold encapsulation 1314 creates a reference plane 1318 on which a second support structure such as a second pillar 1320 is mounted. Above the first pillar 1308 and the second pillar 1320 is a structure such as an interposer 1322. Another structure may be mounted above the interposer 1322 to further increase density.

The first pillar 1308 extends from the reference plane 1306 and contacts the interposer 1322 making the first pillar 1308 a different size than the second pillar 1320 which extends from the reference plane 1318 and contacts the interposer 1322.

The interposer 1322 is shown connected from above to the substrate 1302 with bond wires 1324. Below the interposer 1322 are passive components 1326 such as capacitors, resistors or the like.

Further, above the substrate 1302 the passive components 1326 are also mounted. Below the substrate 1302 are mounted external interconnects such as solder balls 1328. An encapsulation 1330 encapsulates the first pillar 1308, the second pillar 1320, and the pre-mold package 1310 protecting sensitive components from moisture, dust and other contamination.

Referring now to FIG. 14, therein is shown a cross sectional view of an integrated circuit package system 1400 in a thirteenth embodiment of the present invention. The integrated circuit package system 1400 is shown having a substrate 1402 such as a laminated plastic or ceramic substrate with a top surface 1404.

The top surface 1404 of the substrate 1402 creates a reference plane 1406 on which a first support structure such as a first pillar 1408 is mounted. The first pillar 1408 may be an organic or conductive metal pillar.

Also mounted above the substrate 1402 is a wire-bonded die 1410 with an active side 1412. The active side 1412 of the wire-bonded die 1410 is connected to the substrate 1402 with bond wires 1414.

The active side 1412 of the wire-bonded die 1410 creates a reference plane 1416 on which a second pillar 1418 is mounted. The second pillar 1418 and the wire-bonded die 1410 form a second support structure 1419. Above the first pillar 1408 and the second pillar 1418 is a structure such as an ISM 1420. Another structure may be mounted above the ISM 1420 to further increase density.

The first pillar 1408 extends from the reference plane 1406 and contacts the ISM 1420 making the first pillar 1408 a different size than the second pillar 1418 which extends from the reference plane 1416 and contacts the ISM 1420.

The ISM 1420 is shown connected from above to the substrate 1402 with the bond wires 1414. The ISM 1420 is shown having an ISM substrate 1422 with an ISM wire-bonded die 1424 mounted below and having an active side 1426. The active side 1426 of the ISM wire-bonded die 1424 is connected to the ISM substrate 1422 with the bond wires 1414.

Further, above the substrate 1402 passive components 1428 such as capacitors, resistors or the like may be mounted. Below the substrate 1402 are mounted external interconnects such as solder balls 1430.

An encapsulation 1432 encapsulates the first pillar 1408, the second pillar 1418, and the wire-bonded die 1410 protecting sensitive components from moisture, dust and other contamination.

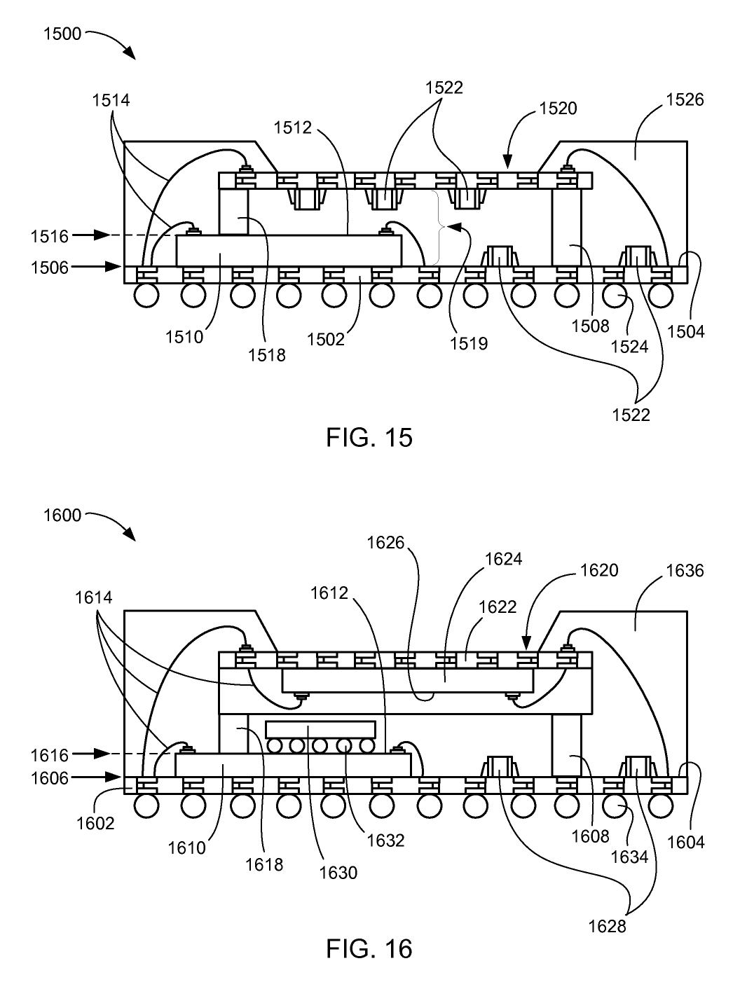

Referring now to FIG. 15, therein is shown a cross sectional view of an integrated circuit package system 1500 in a fourteenth embodiment of the present invention. The integrated circuit package system 1500 is shown having a substrate 1502 such as a laminated plastic or ceramic substrate with a top surface 1504.

The top surface 1504 of the substrate 1502 creates a reference plane 1506 on which a first support structure such as a first pillar 1508 is mounted. The first pillar 1508 may be an organic or conductive metal pillar. Also mounted above the substrate 1502 is a wire-bonded die 1510 with an active side 1512.

The active side 1512 of the wire-bonded die 1510 is connected to the substrate 1502 with bond wires 1514. The active side 1512 of the wire-bonded die 1510 creates a reference plane 1516 on which a second pillar 1518 is mounted.

The second pillar 1518 and the wire-bonded die 1510 form a second support structure 1519. Above the first pillar 1508 and the second pillar 1518 is a structure such as an interposer 1520. Another structure may be mounted above the interposer 1520 to further increase density.

The first pillar 1508 extends from the reference plane 1506 and contacts the interposer 1520 making the first pillar 1508 a different size than the second pillar 1518 which extends from the reference plane 1516 and contacts the interposer 1520.

The interposer 1520 is shown connected from above to the substrate 1502 with the bond wires 1514. Below the interposer 1520 are passive components 1522 such as capacitors, resistors or the like. Further, above the substrate 1502 the passive components 1522 are also mounted. Below the substrate 1502 are mounted external interconnects such as solder balls 1524.

An encapsulation 1526 encapsulates the first pillar 1508, the second pillar 1518, and the wire-bonded die 1510 protecting sensitive components from moisture, dust and other contamination.

Referring now to FIG. 16, therein is shown a cross sectional view of an integrated circuit package system 1600 in a fifteenth embodiment of the present invention. The integrated circuit package system 1600 is shown having a substrate 1602 such as a laminated plastic or ceramic substrate with a top surface 1604.

The top surface 1604 of the substrate 1602 creates a reference plane 1606 on which a first support structure such as a first pillar 1608 is mounted. The first pillar 1608 may be an organic or conductive metal pillar. Also mounted above the substrate 1602 is a wire-bonded die 1610 with an active side 1612.

The active side 1612 of the wire-bonded die 1610 is connected to the substrate 1602 with bond wires 1614. The active side 1612 of the wire-bonded die 1610 creates a reference plane 1616 on which a second support structure such as a second pillar 1618 is mounted. Above the first pillar 1608 and the second pillar 1618 is a structure such as an ISM 1620. Another structure may be mounted above the ISM 1620 to further increase density.

The first pillar 1608 extends from the reference plane 1606 and contacts the ISM 1620 making the first pillar 1608 a different size than the second pillar 1618 which extends from the reference plane 1616 and contacts the ISM 1620.

The ISM 1620 is shown connected from above to the substrate 1602 with the bond wires 1614. The ISM 1620 is shown having an ISM substrate 1622 with an ISM wire-bonded die 1624 mounted below and having an active side 1626.

The active side 1626 of the ISM wire-bonded die 1624 is connected to the ISM substrate 1622 with the bond wires 1614. Further, above the substrate 1602 passive components 1628 such as capacitors, resistors or the like may be mounted.

Between the wire-bonded die 1610 and the ISM 1620 a FC 1630, is mounted to the active side 1612 of the wire-bonded die 1610. The FC 1630 is connected to the wire-bonded die 1610 with internal interconnects such as solder balls 1632.

Below the substrate 1602 are mounted external interconnects such as solder balls 1634. An encapsulation 1636 encapsulates the first pillar 1608, the second pillar 1618, and the wire-bonded die 1610 protecting sensitive components from moisture, dust and other contamination.

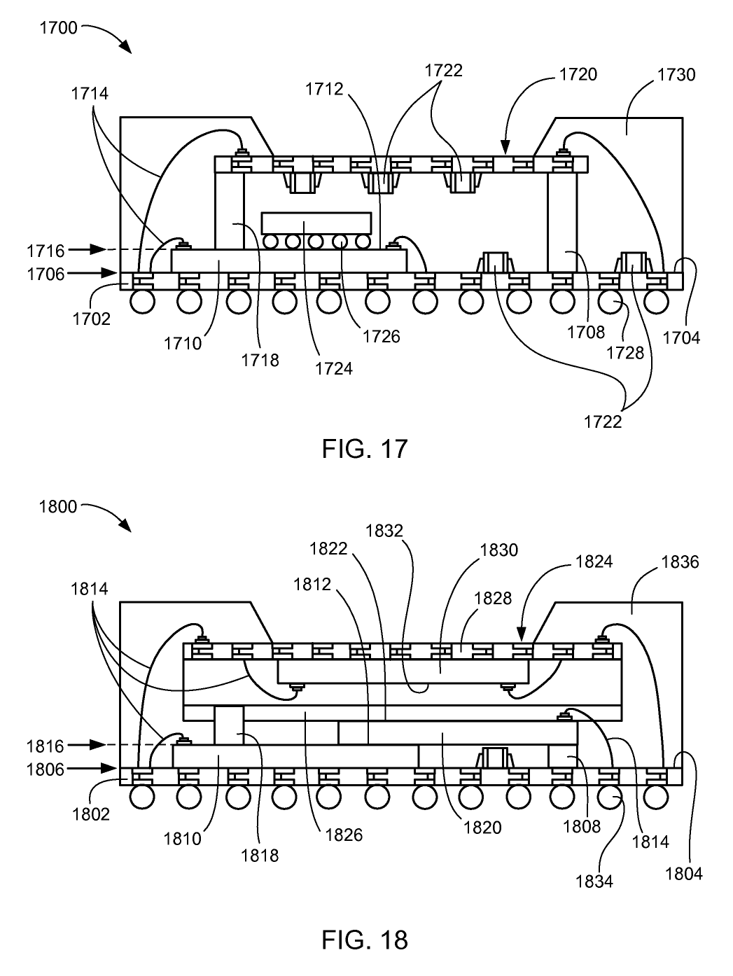

Referring now to FIG. 17, therein is shown a cross sectional view of an integrated circuit package system 1700 in a sixteenth embodiment of the present invention. The integrated circuit package system 1700 is shown having a substrate 1702 such as a laminated plastic or ceramic substrate with a top surface 1704.

The top surface 1704 of the substrate 1702 creates a reference plane 1706 on which a first support structure such as a first pillar 1708 is mounted. The first pillar 1708 may be an organic or conductive metal pillar. Also mounted above the substrate 1702 is a wire-bonded die 1710 with an active side 1712.

The active side 1712 of the wire-bonded die 1710 is connected to the substrate 1702 with bond wires 1714. The active side 1712 of the wire-bonded die 1710 creates a reference plane 1716 on which a second support structure such as a second pillar 1718 is mounted. Above the first pillar 1708 and the second pillar 1718 is a structure such as an interposer 1720. Another structure may be mounted above the interposer 1720 to further increase density.

The first pillar 1708 extends from the reference plane 1706 and contacts the interposer 1720 making the first pillar 1708 a different size than the second pillar 1718 which extends from the reference plane 1716 and contacts the interposer 1720.

The interposer 1720 is shown connected from above to the substrate 1702 with the bond wires 1714. Below the interposer 1720 are passive components 1722 such as capacitors, resistors or the like.

Further, above the substrate 1702 the passive components 1722 are also mounted. Between the wire-bonded die 1710 and the interposer 1720, a FC 1724 is mounted to the active side 1712 of the wire-bonded die 1710. The FC 1724 is connected to the wire-bonded die 1710 with internal interconnects such as solder balls 1726.

Below the substrate 1702 are mounted external interconnects such as solder balls 1728. An encapsulation 1730 encapsulates the first pillar 1708, the second pillar 1718, and the wire-bonded die 1710 protecting sensitive components from moisture, dust and other contamination.

Referring now to FIG. 18, therein is shown a cross sectional view of an integrated circuit package system 1800 in a seventeenth embodiment of the present invention. The integrated circuit package system 1800 is shown having a substrate 1802 such as a laminated plastic or ceramic substrate with a top surface 1804.

The top surface 1804 of the substrate 1802 creates a reference plane 1806 on which a first support structure such as a first pillar 1808 is mounted. The first pillar 1808 may be an organic or conductive metal pillar. Also mounted above the substrate 1802 is a first wire-bonded die 1810 with an active side 1812.

The active side 1812 of the first wire-bonded die 1810 is connected to the substrate 1802 with bond wires 1814. The active side 1812 of the first wire-bonded die 1810 creates a reference plane 1816 on which a second support structure such as a second pillar 1818 is mounted.

Above the first pillar 1808 and the first wire-bonded die 1810 is a second wire-bonded die 1820 with an active side 1822. The active side 1822 of the second wire-bonded die 1820 is connected to the substrate 1802 with the bond wires 1814.

Above the second wire-bonded die 1820 and the second pillar 1818 is a structure such as an ISM 1824. Another structure may be mounted above the ISM 1824 to further increase density. Between the ISM 1824 and the second wire-bonded die 1820, is a wire-in-film adhesive 1826.

The wire-in-film adhesive 1826 has a low viscosity and, as temperature increases, the viscosity gets lower. Therefore, the wire-in-film adhesive 1826 can be easily pressed over the bond wires 1814 and above and around the second wire-bonded die 1820 and then cured to harden the wire-in-film adhesive 1826.

It has been discovered that the wire-in-film adhesive 1826 should be a thermally conductive dielectric material. The wire-in-film adhesive 1826 can be made of a B-stage material that can be hardened after curing and can maintain a predetermined thickness.

The first pillar 1808 extends from the reference plane 1806 and contacts the second wire-bonded die 1820 while the second pillar 1818 extends from the reference plane 1816 through the wire-in-film adhesive 1826 to contact the ISM 1824. In this way, the first pillar 1808 is a different size than the second pillar 1818 because the second pillar 1818 is the height of the second wire-bonded die 1820 and the wire-in-film adhesive 1826.

The ISM 1824 is shown connected from above to the substrate 1802 with the bond wires 1814. The ISM 1824 is shown having an ISM substrate 1828 with an ISM wire-bonded die 1830 mounted below and having an active side 1832.

The active side 1832 of the ISM wire-bonded die 1830 is connected to the ISM substrate 1828 with the bond wires 1814. Below the substrate 1802 are mounted external interconnects such as solder balls 1834.

An encapsulation 1836 encapsulates the first pillar 1808, the second pillar 1818, the first wire-bonded die 1810 and the second wire-bonded die 1820 protecting sensitive components from moisture, dust and other contamination.

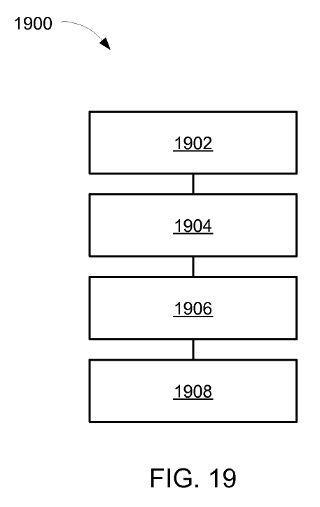

Referring now to FIG. 19, therein is shown a flow chart of an integrated circuit package system 1900 for the manufacture of an integrated circuit package system with non-symmetrical support structures in an embodiment of the present invention. The system 1900 includes providing an integrated circuit package system including: providing a substrate with a wire-bonded die mounted thereover in a block 1902; mounting a first support structure and a second support structure of different size above the substrate in a block 1904; mounting a structure above the first support structure and the second support structure in a block 1906; and encapsulating the wire-bonded die, the first support structure and the second support structure with an encapsulation in a block 1908.

It has been discovered that the present invention thus has numerous aspects.

A principle aspect that has been unexpectedly discovered is that the present invention reduces the number of support structures needed by combining the support functionality with other components in the package.

Another aspect is that the present invention reduces process steps required to provide support in the package.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the non-symmetrical support structure system of the present invention furnishes important and heretofore unknown and unavailable solutions, capabilities, and functional aspects for internal package support.

The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description.

Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. An integrated circuit package system comprising:
providing a substrate with a wire-bonded die mounted thereover;
mounting a first support structure and a second support structure of different size above the substrate;
mounting a structure above the first support structure and the second support structure; and
encapsulating the wire-bonded die, the first support structure and the second support structure with an encapsulation.

2. The system as claimed in claim 1 further comprising:
mounting a wire-in-film adhesive between the wire-bonded die and the structure, and where the first support structure penetrates the wire-in-film adhesive.

3. The system as claimed in claim 1 further comprising:
mounting a wire-in-film adhesive between the wire-bonded die and the structure, and where the first support structure does not penetrate the wire-in-film adhesive.

4. The system as claimed in claim 1 further comprising:
mounting a wire-in-film adhesive between the wire-bonded die and the structure; and
mounting a flip chip or a pre-mold package above the substrate where the wire-bonded die is mounted above the flip chip or the pre-mold package and where the wire-bonded die and the flip chip or the pre-mold package comprise the second support structure.

5. The system as claimed in claim 1 further comprising:
mounting a first wire-bonded die above the substrate where the wire-bonded die and the first support structure are mounted thereover.

6. An integrated circuit package system comprising:
providing a substrate with a wire-bonded die mounted thereover;
mounting a first pillar and a second support structure including the wire-bonded die, a second pillar of different size than the first pillar, or a combination thereof, above the substrate;
mounting a structure above the first pillar and the second support structure; and
encapsulating the wire-bonded die, the first pillar and the second support structure with an encapsulation.

7. The system as claimed in claim 6 wherein:
providing the substrate with a wire-bonded die mounted thereover includes mounting a pre-mold package above the substrate; and
mounting the second support structure includes mounting the second pillar over the pre-mold package.

8. The system as claimed in claim 6 further comprising:
mounting a second wire-bonded die between the first pillar and the structure and above the wire-bonded die.

9. The system as claimed in claim 6 further comprising:
mounting a flip chip or a passive component between the substrate and the structure.

10. The system as claimed in claim 6 wherein:
mounting the structure includes mounting an interposer or an inner stacking module.

11. An integrated circuit package system comprising:
a substrate with a wire-bonded die mounted thereover;
a first support structure and a second support structure of different size mounted above the substrate;
a structure mounted above the first support structure and the second support structure; and
an encapsulation encapsulating the wire-bonded die, the first support structure and the second support structure.

12. The system as claimed in claim 11 further comprising:
a wire-in-film adhesive mounted between the wire-bonded die and the structure, and where the first support structure penetrates the wire-in-film adhesive.

13. The system as claimed in claim 11 further comprising:
a wire-in-film adhesive mounted between the wire-bonded die and the structure, and where the first support structure does not penetrate the wire-in-film adhesive.

14. The system as claimed in claim 11 further comprising:
a wire-in-film adhesive mounted between the wire-bonded die and the structure; and
a flip chip or a pre-mold package mounted above the substrate where the wire-bonded die is mounted above the flip chip or the pre-mold package and where the wire-bonded die and the flip chip or the pre-mold package comprise the second support structure.

15. The system as claimed in claim 11 further comprising:
a first wire-bonded die mounted above the substrate where the wire-bonded die and the first support structure are mounted thereover.

16. The system as claimed in claim 11 wherein:
the first support structure is a first pillar; and
the second support structure includes the wire-bonded die, a second pillar of different size than the first pillar, or a combination thereof.

17. The system as claimed in claim 16 wherein:
the wire-bonded die mounted thereover is part of a pre-mold package above the substrate; and
the second support structure is the second pillar mounted over the pre-mold package.

18. The system as claimed in claim 16 further comprising:
a second wire-bonded die mounted between the first pillar and the structure and mounted above the wire-bonded die.

19. The system as claimed in claim 16 further comprising:
a flip chip or a passive component mounted between the substrate and the structure.

20. The system as claimed in claim 16 wherein:
the structure is an interposer or an inner stacking module.
